(19) United States
(12) Patent Application Publication
(10) Pub. No.: US 2026/0031307 A1
(43) Pub. Date: Jan. 29, 2026

(54) HOLDING DEVICE

(71) Applicant: Niterra Co., Ltd., Nagoya-shi, Aichi (JP)

(72) Inventors: Yasuaki KIMIKADO, Nagoya-shi, Aichi (JP); Daisuke UEMATSU, Nagoya-shi, Aichi (JP); Honami OHARA, Nagoya-shi, Aichi (JP); Takumi SANARI, Nagoya-shi, Aichi (JP)

(21) Appl. No.: 19/119,519

(22) PCT Filed: Feb. 22, 2024
(86) PCT No.: PCT/JP2024/006547

§ 371 Date: Apr. 9, 2025

(30) Foreign Application Priority Data
Apr. 19, 2023 (JP) 2023-068397

(51) Int. Cl. H01J 37/32

(52) U.S. Cl. CPC H01J 37/32715; H01J 37/3244; H01J 2237/0206; H01J 2237/2007; H01J 2237/334

(57) ABSTRACT

A holding device includes: a holding substrate which includes a first surface and an opposed second surface, a first gas flow passage formed therein and having a first gas outlet open to the first surface and a first gas inlet which is open to the second surface, and a gas permeable first porous body disposed in the first gas flow passage and containing a ceramic material as a main component; and a base which includes a third surface opposed to the second surface and an opposed fourth surface, a second gas flow passage formed therein and having a second gas outlet open to the third surface, and a gas permeable second porous body disposed in the second gas flow passage and containing a ceramic material as a main component. A plasma resistance of the first porous body is higher than a plasma resistance of the second porous body.

### TECHNICAL FIELD

The present invention relates to a holding device.

### BACKGROUND ART

An electrostatic chuck has been known as a holding device for holding a wafer (semiconductor wafer) in production of semiconductors (see Patent Document 1). The electrostatic chuck has a holding substrate (ceramic substrate) formed mainly of an insulating ceramic material (for example, alumina), and a wafer is held on a surface of the holding substrate by electrostatic attraction. Electrostatic attraction is generated when a voltage is applied to chuck electrodes provided in the holding substrate.

In an electrostatic chuck of this type, when used in a plasma process such as plasma etching, a heat conduction gas (inert gas) such as helium gas is supplied between the holding substrate and a wafer, thereby removing heat from the wafer. Therefore, a gas flow passage through which the heat conduction gas supplied from the outside is caused to flow toward the wafer is formed in the holding substrate of the electrostatic chuck. A plurality of gas outlets located at the end of the gas flow passage are provided on the surface of the holding substrate, and the heat conduction gas is supplied from each gas outlet toward the wafer.

In some cases, abnormal discharge (arcing) occurs in the gas flow passage due to high-frequency power applied during the plasma process, and the abnormal discharge damages the wafer on the holding substrate. Therefore, in order to prevent occurrence of such abnormal discharge, a gas permeable porous body formed of an insulating ceramic material is provided in the gas flow passage.

### PRIOR ART DOCUMENT

### Patent Document

Patent Document 1: Japanese Patent No. 4959905

### Problem to be Solved by the Invention

The porous body used as a countermeasure against abnormal discharge as described above is required to have plasma resistance and gas permeability for allowing permeation of a gas at a sufficiently large flow rate. However, there is a competing relationship between gas permeability and plasma resistance of the porous body, which brings about a problem; for example, an attempt to improve the gas permeability of the porous body results in lowering of the plasma resistance, and an attempt to improve the plasma resistance of the porous body results in lowering of the gas permeability. Therefore, the conventional holding device has room for improvement of the porous body.

### SUMMARY OF THE INVENTION

An object of the present invention is to provide a holding device including a porous body which is provided in a gas flow passage for supplying an inert gas and which has gas permeability and is excellent in plasma resistance.

### Means for Solving the Problem

Means for solving the above-described problem are as follows.
<1>A holding device comprising:
   a holding substrate which includes a plate-shaped member having a first surface and a second surface located on a side opposite the first surface, a first gas flow passage formed in the plate-shaped member and having a first gas outlet which is open to the first surface side and a first gas inlet which is open to the second surface side, and a gas permeable first porous body disposed in the first gas flow passage and containing a ceramic material as a main component; and
   a base which includes a plate-shaped base member disposed on the second surface side of the plate-shaped member and having a third surface opposed to the second surface and a fourth surface located on a side opposite the third surface, a second gas flow passage formed in the plate-shaped base member and having a second gas outlet which is open to the third surface side and is opposed to the first gas inlet, and a gas permeable second porous body disposed in the second gas flow passage and containing a ceramic material as a main component, wherein
   the first gas flow passage has a first vertical flow passage portion which extends from the first gas inlet toward the first surface side and in which the first porous body is disposed,
   the second gas flow passage has a second vertical flow passage portion which extends from the second gas outlet toward the fourth surface side and in which the second porous body is disposed in such a manner as to overlap with the first porous body in a plan view, and
   the first porous body is higher in plasma resistance than the second porous body.
<2>The holding device described in the above paragraph <1>, wherein the ceramic material of the first porous body is higher in purity than the ceramic material of the second porous body.
<3>The holding device described in the above paragraph <1>or <2>, wherein the ceramic material of the first porous body is alumina, and the ceramic material of the second porous body is alumina.
<4>The holding device described in the above paragraph <1>or <2>, wherein the ceramic material of the first porous body is yttria, and the ceramic material of the second porous body is alumina.
<5>The holding device described in any one of the above paragraphs <1>to <4>, wherein the first porous body has a porosity of 50 to 80% and the second porous body has a porosity equal to or higher than the porosity of the first porous body.
<6>The holding device described in any one of the above paragraphs <1>to <6>, wherein the first vertical flow passage portion extends in a thickness direction of the plate-shaped member so as to connect the first gas outlet and the first gas inlet, and
   the first porous body is disposed to fill the first vertical flow passage portion from the first gas outlet side to the first gas inlet.
<7>The holding device described in any one of the above paragraphs <1>to <6>, wherein the plate-shaped member contains a ceramic material as a main component, and the plate-shaped member and the first porous body are joined to each other by means of sintering.
<8>The holding device described in the above paragraph <1>or <2>, wherein each of the first porous body and the second porous body contains a glass component, and the first porous body is smaller in glass content than the second porous body.

### Effect of the Invention

According to the present invention, it is possible to provide a holding device including a porous body which is provided in a gas flow passage for supplying an inert gas and which has gas permeability and is excellent in plasma resistance.

### BRIEF DESCRIPTION OF THE DRAWINGS

FIG. 1 is an explanatory view schematically representing the sectional structure of a holding device according to Embodiment 1.

FIG. 2 is a sectional view of the holding device, which shows, on an enlarged scale, an area where a first gas flow passage and a second gas flow passage are connected and its vicinity.

FIG. 3 is an explanatory view showing the positional relation between an upper end surface of a first porous body and an upper end surface of a second porous body in a plan view.

FIG. 4A, FIG. 4B, FIG. 4C, and FIG. 4D are explanatory views schematically representing a method of producing a holding substrate.

FIG. 5A, FIG. 5B, and FIG. 5C are explanatory views schematically representing a method of producing a base.

FIG. 6 is a sectional view of a holding device according to Embodiment 2, which shows, on an enlarged scale, an area where the first gas flow passage and the second gas flow passage are connected and its vicinity.

FIG. 7 is a sectional view of a holding device according to Embodiment 3, which shows, on an enlarged scale, an area where the first gas flow passage and the second gas flow passage are connected and its vicinity.

FIG. 8 is a sectional view of a holding device according to Embodiment 4, which shows, on an enlarged scale, an area where the first gas flow passage and the second gas flow passage are connected and its vicinity.

FIG. 9 is an explanatory view schematically representing the sectional structure of a portion of a holding device according to Embodiment 5.

### MODES FOR CARRYING OUT THE INVENTION

### Embodiment 1

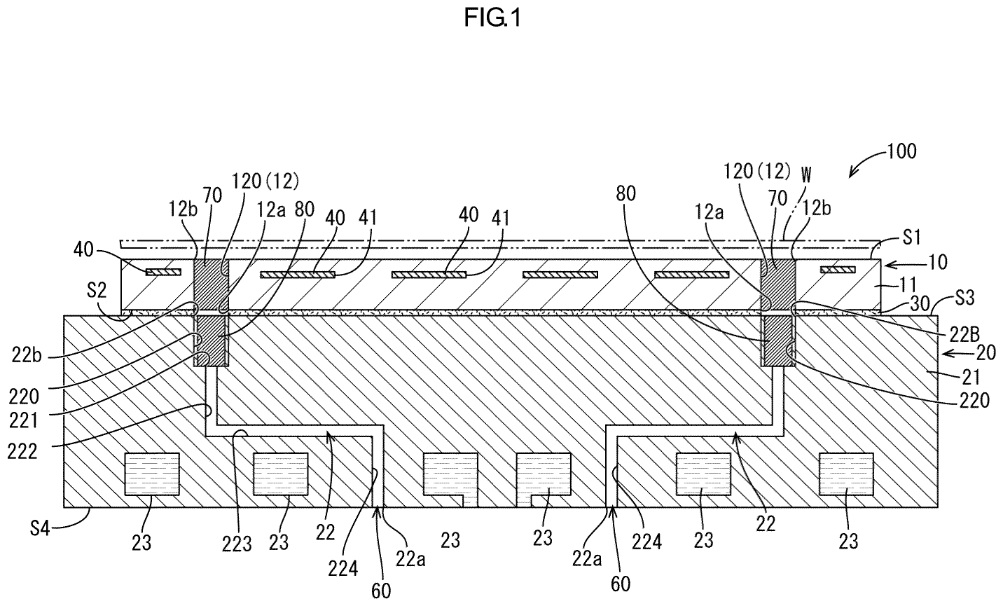

A holding device 100 according to Embodiment 1 will now be described with reference to FIGS. 1 to 5. The holding device 100 is an electrostatic chuck which attracts and holds an object (for example, a wafer W) by electrostatic attraction. For example, in a process of performing etching by using plasma in a depressurized chamber, the electrostatic chuck is used as a table on which the wafer W is placed.

FIG. 1 is an explanatory view schematically representing the sectional structure of the holding device 100 according to Embodiment 1. FIG. 1 schematically shows the sectional structure of the holding device 100 observed when the holding device 100 is cut in a vertical direction (an upward/downward direction). The holding device 100 includes a disc-shaped holding substrate (ceramic substrate) 10 and a disk-shaped base (base member) 20, which is larger than the holding substrate 10.

The holding substrate 10 and the base 20 are stacked on top of each other in the upward/downward direction in a state in which the holding substrate 10 is located on the upper side, and the base 20 is located on the lower side. The holding substrate 10 and the base 20 are joined to each other by a joining material 30 intervening therebetween.

The holding substrate 10 has an approximately circular first surface S1 which is located on the upper side, and an approximately circular second surface S2 which is located on the side opposite the first surface S1 (namely, on the lower side) and is opposed to the base 20. The base 20 has an approximately circular third surface S3 which is located on the upper side and is opposed to the second surface S2 of the holding substrate 10, and an approximately circular fourth surface S4 which is located on the side opposite the third surface S3 (namely, on the lower side). The joining material 30 described above is sandwiched between the second surface S2 of the holding substrate 10 and the third surface S3 of the base 20 and extends to form a layer.

The holding substrate 10 has a disc-like, plate-shaped member 11 and a first gas flow passage 12 formed in the plate-shaped member 11. A surface of the plate-shaped member 11 on the upper side serves as the first surface S1 of the holding substrate 10, and a surface of the plate-shaped member 11 on the lower side serves as the second surface S2 of the holding substrate 10.

The plate-shaped member 11 is a plate-shaped (disc-shaped) insulating member whose main component is a ceramic material. In the present specification, the “main component” means a component which is the largest in content. The plate-shaped member 11 of the present embodiment is formed of alumina (Al₂O₃). Notably, in other embodiments, the plate-shaped member 11 may be formed of any of other ceramic materials such as aluminum nitride (AlN).

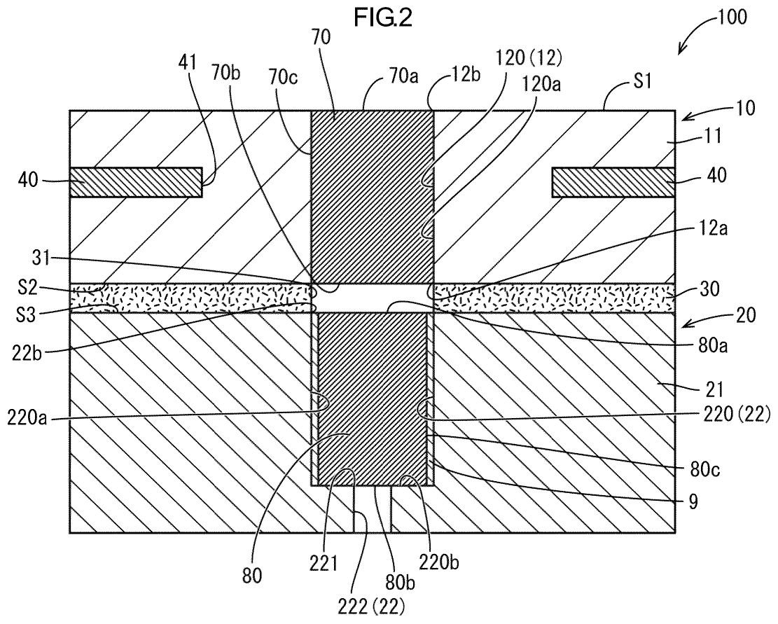

FIG. 2 is a sectional view of the holding device 100, which shows, on an enlarged scale, an area where a first gas flow passage 12 and a second gas flow passage 22 are connected and its vicinity. FIG. 2 schematically shows the sectional structure of the holding substrate 10 observed when the holding substrate 10 is cut in a thickness direction (the upward/downward direction). The first gas flow passage 12 partially constitutes a flow passage 60 which is provided in the holding device 100 and through which an inert gas (for example, helium gas, which is a heat conduction gas) flows. The first gas flow passage 12 is formed in the plate-shaped member 11 of the holding substrate 10. The first gas flow passage 12 is composed of a hole which penetrates the holding substrate 10 in the thickness direction (the upward/downward direction) and which includes a first gas inlet 12a which is open toward the second surface S2 side of the holding substrate 10 (the plate-shaped substrate 11) and a gas outlet 12b which is open toward the first surface S1 side of the holding substrate 10. When an inert gas is supplied to the first gas flow passage 12 through the first gas inlet 12a, the inert gas flows through the first gas flow passage 12 and is finally discharged to the outside through the first gas outlet 12b.

The first gas flow passage 12 has a cylindrical first vertical flow passage portion 120 which extends from the first gas inlet 12a toward the first surface S1 side in the thickness direction of the plate-shaped member 11 (the upward/downward direction). In the case of the present embodiment, the entire first gas flow passage 12 is composed of the first vertical flow passage portion 120. The first vertical flow passage portion 120 is shaped to extend in the thickness direction of the plate-shaped member 11, thereby connecting the first gas outlet 12b and the first gas inlet 12a. A gas permeable first porous body 70 (which will be described later) whose main component is a ceramic material is disposed in the first vertical flow passage portion 120.

Notably, in the first gas flow passage 12, the first gas inlet 12a side is the upstream side, and the first gas outlet 12b side is the downstream side.

The holding substrate 10 further includes chuck electrodes 40, which are electrode members. The chuck electrodes 40, as a whole, form a plane (layer) which is approximately parallel to the first surface S1. The chuck electrodes 40 are formed of, for example, an electrically conductive material such as tungsten, molybdenum, platina, etc. The chuck electrodes 40 are disposed in the holding substrate 10 (the plate-shaped member 11) to be located on the first surface S1 side. The chuck electrodes 40 are connected to an external power source via terminals or the like. When electricity is supplied to the chuck electrodes 40, electrostatic attraction is generated, and the wafer W is attracted to and held on the first surface S1 of the holding substrate 10 by the electrostatic attraction. The chuck electrodes 40 have through holes 41 which penetrate them in the thickness direction (the upward/downward direction). Notably, in other embodiments, the holding substrate 10 may include a high-frequency electrode and/or a heater electrode as an electrode member.

A plurality of (many) first gas outlets 12b are provided on the first surface S1 of the holding substrate 10. For convenience of description, only two of the first gas outlets 12b are shown in FIG. 1.

The base 20 includes a disc-like, plate-shaped base member 21 and a second gas flow passage 22 formed in the plate-shaped base member 21.

The plate-shaped base member 21 is a plate-shaped member which constitutes the base (base member) 20 and is formed of a metallic material. The plate-shaped base member 21 has the third surface S3 opposed to the second surface S2 of the holding substrate 10 (the plate-shaped member 11) and the fourth surface S4 located on the side opposite to the third surface S3. The plate-shaped base member 21 is disposed on the second surface S2 side of the plate-shaped member 11 of the holding substrate 10.

The plate-shaped base member 21 of the base 20 is formed of, for example, a metal (aluminum, aluminum alloy, etc.), a metal-based material such as a metal-ceramic composite (Al-SiC), or a ceramic material such as SiC.

A refrigerant flow passage 23 is provided in the base 20. A refrigerant (for example, fluorine-based inert liquid, water, etc.) is caused to flow through the refrigerant flow passage 23, thereby cooling plasma heat. In addition, when the refrigerant is caused to flow through the refrigerant flow passage 23, the base 20 is cooled, and, as a result of heat transfer (heat removal) between the base 20 and the holding substrate 10 through the joining material 30, the holding substrate 10 is cooled. As a result, the wafer W held on the first surface S1 of the holding substrate 10 is cooled. Notably, the temperature of the wafer W held on the first surface S1 can be controlled by appropriately adjusting the flow rate of the refrigerant flowing through the refrigerant flow passage 23.

The second gas flow passage 22 is provided in the base 20 and partially constitutes the flow passage 60. The second gas flow passage 22 has the shape of a hole penetrating the base 20 and has a second gas outlet 22b which is open toward the third surface S3 side of the plate-shaped base member 21 and is opposed to the first gas inlet 12a, and a second gas inlet 22a which is open toward the fourth surface S4 side of the plate-shaped base member 21. The second gas inlet 22a serves as an inlet of the second gas flow passage 22 and also serves as an inlet of the entire flow passage 60 provided in the holding device 100.

Notably, in the second gas flow passage 22, the second gas inlet 22a is the upstream side, and the second gas outlet 22b side is the downstream side.

The second gas flow passage 22 has a cylindrical second vertical flow passage portion 220 which extends from the second gas outlet 22b toward the fourth surface S4 side in the thickness direction of the plate-shaped base member 21 (the upward/downward direction). In the case of the present embodiment, the second vertical gas flow passage 220 has the shape of a bottomed cylinder, and the open end of the second vertical gas flow passage 220 serves as the second gas outlet 22b. A gas permeable second porous body 80 (which will be described later) whose main component is a ceramic material is disposed in the second vertical flow passage portion 220.

The second vertical flow passage portion 220 has a cylindrical circumferential surface 220a and a bottom surface 220b which is located on the fourth surface S4 side of the circumferential surface 220a and has a circular shape in the plan view. An opening 221 is provided at an approximate center of the bottom surface 220b. A tubular vertical flow passage portion 222 is provided on the fourth surface S4 side in relation to the opening 221 and extends in the thickness direction of the plate-shaped base member 21. A horizontal flow passage portion 223 extending along and parallel to the third surface S3 is provided at the lower end of the vertical flow passage portion 222. In addition, a tubular vertical flow passage portion 224 is provided. The vertical flow passage portion 224 extends from the upstream-side end of the vertical flow passage portion 222 toward the fourth surface S4 side in the thickness direction of the plate-shaped base member 21. Notably, the inner diameters of the vertical flow passage portion 222, the horizontal flow passage portion 223, and the vertical flow passage portion 224 are smaller than the inner diameter of the second vertical flow passage portion 220.

The joining material 30 is composed of, for example, a bonding sheet which contains, for example, a silicone-based organic joining agent, an inorganic joining agent, or an Al-based metal adhesive. A joining agent or adhesive which exhibits high bonding force to both of the holding substrate 10 and the base 20 and has high pressure resistance and high heat conductivity is preferably used as the joining material 30.

In the joining material 30 as well, a joint-side gas flow passage 31 which partially constitutes the flow passage 60 is formed. The joint-side gas flow passage 31 is composed of a hole which penetrates the layer-shaped joining material 30 in the thickness direction.

The flow passage 60 is used to supply an inert gas (helium gas, etc.) to the first surface S1 side of the holding device 100. As described above, many first gas outlets 12b, which serve as the outlet of the flow passage 60, are provided on the first surface S1, and the inert gas is discharged from each first gas outlet 12b, whereby the inert gas is supplied to the first surface S1 side. As described above, the flow passage 60 is composed of the second gas flow passage 22, the joint-side gas flow passage 31, and the first gas flow passage 12.

The inlet of the flow passage 60 is composed of a plurality of second gas inlets 22a provided on the fourth surface S4 of the base 20 (the plate-shaped base member 21). When an inert gas is supplied from each second gas inlet 22a, the inert gas passes through the second gas flow passage 22 connected to the second gas inlet 22a, the joint-side gas flow passage 31, and the first gas flow passage 12, and is finally discharged from the plurality of first gas outlets 12b provided on the first surface S1.

The second gas outlet 22b of each second gas flow passage 22 is connected to the opening of a corresponding joint-side gas flow passage 31 on the lower side (the base 20 side). In addition, the opening of the corresponding joint-side gas flow passage 31 on the upper side (the holding substrate 10 side) is connected to the first gas inlet 12a of a corresponding one of the plurality of first gas flow passages 12. The first gas inlets 12a of the first gas flow passages 12 are provided on the second surface S2 of the holding substrate 10.

A plurality of unillustrated vertical flow passage portions and a plurality of unillustrated second vertical flow passage portions are connected to the horizontal flow passage portion 223 of the above-described second gas flow passage 22. Such second gas flow passage 22 is branched in the base 20 (the plate-shaped base member 21) at a plurality of locations from the upstream side toward the downstream side. The first gas flow passage (the first vertical flow passage portion) which is not shown and is formed in the holding substrate 10 (the plate-shaped member 11) is connected to each second vertical flow passage portion.

Next, the first porous body 70 disposed in the first gas flow passage 12 and the second porous body 80 disposed in the second gas flow passage 22 will be described in detail.

The first porous body 70 and the second porous body 80 suppress occurrence of abnormal discharge (arcing) in the first gas flow passage 12 and the second gas flow passage 22 due to the inert gas (helium).

The first porous body 70 is disposed in the first vertical flow passage portion 120 of the first gas flow passage 12 provided in the holding substrate 10. The first porous body 70 is a gas permeable member whose main component is an insulating ceramic material and has a large number of pores. The first porous body 70 has the shape of a circular column extending in the upward/downward direction (the thickness direction of the holding substrate 10), and has a network of gas passages formed therein so as to allow the inert gas to pass therethrough. Namely, the first porous body 70 has a so-called open-cell structure. The gas passages are formed in the first porous body 70 by a large number of pores which communicate with one another. The pores are formed as a result of burning (disappearance) of granular pore-forming material at the time of production (firing) of the first porous body 70. For example, synthetic resin beads, carbon powder, etc. are used as the pore-forming material.

An upper end surface 70a of the first porous body 70 has a circular shape in the plan view and is exposed upward from the gas outlet 12b which is open toward the first surface S1 side of the plate-shaped member 11. In the case of the present embodiment, the first surface S1 and the upper end surface 70a are disposed to be flush with each other. A lower end surface 70b of the first porous body 70 has a circular shape in the plan view and is exposed downward (toward the second porous body 80) from the first gas inlet 12a which is open toward the second surface S2 side of the plate-shaped member 11. The upper end surface 70a and the lower end surface 70b have the same size. In the case of the present embodiment, the second surface S2 and the lower end surface 70b are disposed to be flush with each other. A circumferential surface 70c of the first porous body 70 and a cylindrical inner circumferential surface 120a of the first vertical flow passage portion 120 (the plate-shaped member 11) are joined to each other by means of sintering. Namely, the first porous body 70 and the first vertical flow passage portion 120 (the plate-shaped member 11) are united with each other by means of solid phase bonding.

The second porous body 80 is disposed in the second vertical flow passage portion 220 of the second gas flow passage 22 provided in the base 20. Like the first porous body 70, the second porous body 80 is a gas permeable member whose main component is an insulating ceramic material and has a large number of pores. The second porous body 80 has the shape of a circular column extending in the upward/downward direction (the thickness direction of the base 20), and has a network of gas passages formed therein so as to allow the inert gas to pass therethrough. Namely, the second porous body 80 has a so-called open-cell structure. The gas passages are formed in the second porous body 80 by a large number of pores which communicate with one another. The pores are formed as a result of burning (disappearance) of granular pore-forming material at the time of production (firing) of the second porous body 80. As in the case of the first porous body 70, for example, synthetic resin beads, carbon powder, etc. are used as the pore-forming material.

An upper end surface 80a of the second porous body 80 has a circular shape in the plan view and is exposed to face the first porous body 70 located thereabove from the second gas outlet 22b which is open toward the third surface S3 side of the plate-shaped base member 21. In the case of the present embodiment, the third surface S3 and the upper end surface 80a are disposed to be flush with each other. A lower end surface 80b of the second porous body 80 has a circular shape in the plan view and is laid on the bottom surface 220b of the second vertical flow passage portion 220. A portion of the lower end surface 80b, which portion overlaps with the opening 221 provided at the approximate center of the bottom surface 220b, is exposed to the vertical flow passage portion 220 side. The inert gas supplied from the vertical flow passage portion 222 side is introduced into the second porous body 80 through the exposed portion of the lower end surface 80b. The upper end surface 80a and the lower end surface 80b, and the upper end surface 70a and the lower end surface 70b, have the same size. An adhesive 9 is interposed between a circumferential surface 80c of the second porous body 80 and a circumferential surface 220a of the second vertical flow passage portion 220, and the second porous body 80 is fixed in the second vertical flow passage portion 220 by using the adhesion force of the adhesive 9.

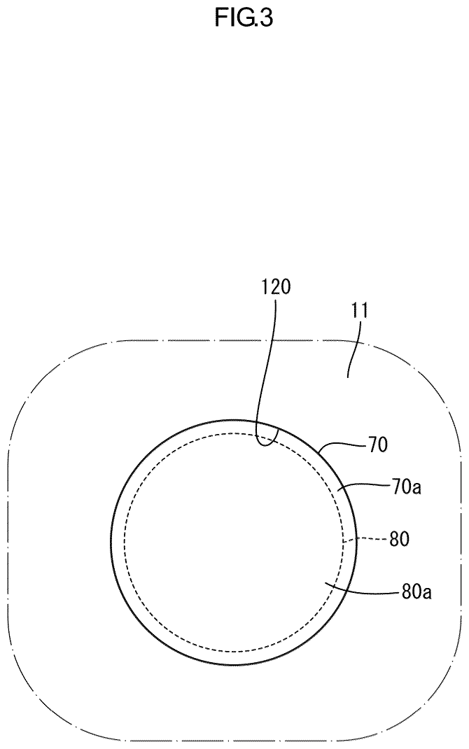

The second porous body 80 is disposed in the second vertical flow passage portion 220 in such a manner as to overlap with the first porous body 70 in the plan view. FIG. 3 is an explanatory view showing the positional relation between the upper end surface 70a of the first porous body 70 and the upper end surface 80a of the second porous body 80 in the plan view. As shown in FIG. 3, when the holding device 100 is viewed from the upper side (the first surface S1 side), the first porous body 70 in the first vertical flow passage portion 120 and the second porous body 80 in the second vertical flow passage portion 220 are disposed such that they overlap with each other. Notably, in the case of the present embodiment, the diameter (outer diameter) of the first porous body 70 is set to be larger than the diameter (outer diameter) of the second porous body 80. In other embodiments, the diameter of the first porous body and the diameter of the second porous body may be equal to each other.

The resistance to plasma (plasma resistance) of the first porous body 70 is set to be higher than the resistance to plasma (plasma resistance) of the second porous body 80.

In the present specification, a portion of the first porous body 70 other than pores may be referred to as a “first skeleton portion,” and a portion of the second porous body 80 other than pores may be referred to as a “second skeleton portion.”

In the case of the present embodiment, the ceramic material which constitutes the first porous body 70 (namely, the ceramic material which constitutes the first skeleton portion) is the same as the ceramic material which constitutes the second porous body 80 (namely, the ceramic material which constitutes the second skeleton portion). Specially, both the ceramic material which constitutes the first porous body 70 and the ceramic material which constitutes the second porous body 80 are alumina.

The purity of the ceramic material (alumina) which constitutes the first porous body 70 is set to be higher than the purity of the ceramic material (alumina) which constitutes the second porous body 80.

No particular limitation is imposed on the purity of the ceramic material (alumina) which constitutes the first porous body 70 so long as the purpose of the present invention is not impaired. However, the purity of the ceramic material which constitutes the first porous body 70 is, for example, preferably 99.0% or higher, more preferably 99.9% or higher.

In addition, the glass content (content percentage) of the first porous body 70 is preferably less than the glass content (content percentage) of the second porous body 80. Each of the first porous body 70 (the first skeleton portion) and the second porous body 80 (the second skeleton portion) contains a glass component (SiO₂) originating from a binder used in production.

The glass content of the first porous body 70 is, for example, preferably less than 0.1%. Since the glass component easily bonds to fluorine, which is used as an etching gas, and becomes a cause of reducing plasma resistance, it is preferred that the glass content of the first porous body 70 is small.

In addition, the glass content of the second porous body 80 is, for example, preferably 0.1% or greater and 10% or less. In the case where the amount of the glass component is large, low-temperature sintering of ceramic powder such as alumina powder becomes easy. In a porous body, such as the second porous body 80, in general, the contact areas between the ceramic powder particles is small, as compared with a dense body, because of its structure. Therefore, sinterability tends to drop. However, addition of a glass component into the ceramic powder as a binder facilitate production of the porous body. In addition, in such a case, since the ceramic powder can be easily sintered at low temperature, the energy needed to produce the porous body can be reduced, which is advantageous from the viewpoint of cost.

In addition, no particular limitation is imposed on the purity of the ceramic material (alumina) which constitutes the second porous body 80 so long as the purpose of the present invention is not impaired. However, the purity of the ceramic material which constitutes the second porous body 80 is, for example, preferably 95.0% or higher, more preferably 97.0% or higher.

Notably, the purities of the ceramic materials of the first porous body 70 and the second porous body 80 can be adjusted by appropriately setting the purity of ceramic powder used in production of the first porous body 70 and the second porous body 80 and the amounts of components to be used other than ceramic powder (for example, binder, dispersant, plasticizer, etc.).

In addition, the porosity of the second porous body 80 is preferably set to be equal to or higher than the porosity of the first porous body 70. Setting the porosity of the first porous body 70 and the porosity of the second porous body 80 in the above-described manner makes it easy to set the plasma resistance of the second porous body 80 to be higher than the plasma resistance of the first porous body 70.

Notably, no particular limitation is imposed on the porosity of the first porous body 70 so long as the purpose of the present invention is not impaired. However, the porosity of the first porous body 70 is, for example, preferably 50% or higher, more preferably 55% or higher, further preferably 60% or higher, and preferably 80% or lower, more preferably 75% or lower, further preferably 70% or lower. When the porosity of the first porous body 70 falls in such ranges, it is easy to set the porosity of the second porous body 80 to be equal to or higher than the porosity of the first porous body 70 while securing the gas permeabilities of the first porous body 70 and the second porous body 80.

As shown in FIG. 2, when an inert gas from the outside is supplied through the second gas inlet 22a, which is the inlet of the flow passage 60, the inert gas sequentially passes through the vertical flow passage portion 224, the horizontal flow passage portion 223, and the vertical flow passage portion 222, which constitute the second gas flow passage 22, and reaches the second vertical flow passage portion 220 connected to the downstream-side end portion of the vertical flow passage portion 222. The inert gas having reached the second vertical flow passage portion 220 enters the second vertical flow passage portion 220 through the opening 221 provided on the bottom surface 220b and is introduced into the second porous body 80 through the lower end surface 80b exposed from the opening 221. The inert gas introduced into the second porous body 80 passes though the gas passage within the second porous body 80 and is discharged to the joint-side gas flow passage 31 side through the upper end surface 80a in the second gas outlet 22b. The discharged inert gas passes through the joint-side gas flow passage 31 and is introduced into the first porous body 70 disposed in the first vertical flow passage portion 120 through the lower end surface 70b in the first gas inlet 12a. The inert gas introduced into the first porous body 70 passes through the gas passage within the first porous body 70 and is discharged to the outside through the upper end surface 70a in the first gas outlet 12b.

As described above, in the holding device 100 of the present embodiment, the inert gas passes through the first porous body 70 and the second porous body 80, which are disposed to overlap with each other as viewed in the upward/downward direction, and is discharged from the first gas outlet 12b provided on the first surface S1 side of the holding substrate 10.

The first porous body 70 disposed in the first gas flow passage 12 (the first vertical flow passage portion 120) of the holding substrate 10 is more likely to be exposed to plasma in a plasma process (plasma etching, etc.) as compared with the second porous body 80, which is disposed below the first porous body 70 such that the second porous body 80 overlaps with the first porous body 70. However, in the holding device 100 of the present embodiment, as described above, the resistance to plasma (plasma resistance) of the first porous body 70 is set to be higher than the resistance to plasma (plasma resistance) of the second porous body 80. Therefore, in the holding device 100 of the present embodiment, in particular, damage of the first porous body 70 by plasma is suppressed, while the gas permeability of the first porous body 70 is secured.

The holding device 100 of the present embodiment includes the first porous body 70 and the second porous body 80 (examples of the porous body) which are provided in the first gas flow passage 12 and the second gas flow passage 22 (examples of the gas flow passage) for supplying the inert gas and which are excellent in plasma resistance while having gas permeability.

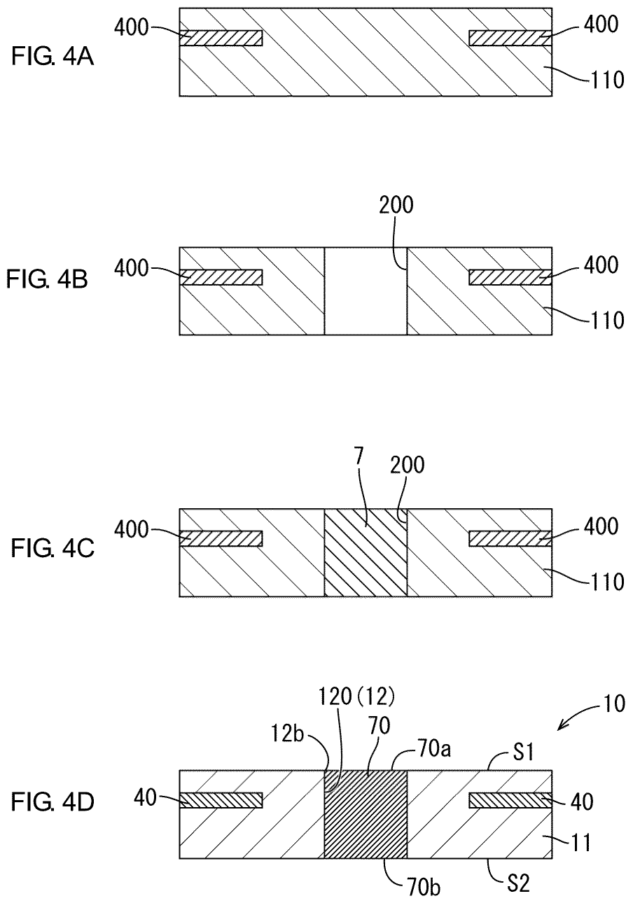

Next, an example of a method of producing the holding device 100 of the present embodiment will be described. A method of producing the holding substrate 10, which constitutes the holding device 100, will first be described with reference to FIGS. 4A-4D. FIGS. 4A-4D are a set of explanatory views schematically representing the method of producing the holding substrate 10. This method of producing the holding substrate 10 is an application of a sheet lamination method in which green sheets (ceramic green sheets) are used.

First, as shown in FIG. 4A, a plurality of green sheets for forming the plate-shaped member 11 of the holding substrate 10 are stacked to form a first laminate 110. Notably, a conductor layer 400 is formed in a predetermined green sheet which constitutes the first laminate 110, and such a green sheet is stacked on other green sheets.

Slurry for the green sheets is obtained by, for example, adding an organic solvent to a mixture containing alumina powder, an acrylic binder, a dispersant, a plasticizer, etc., followed by mixing by using a ball mill. The obtained slurry is formed into a sheet shape by using a casting apparatus, and subsequently, the formed sheets are dried, whereby the plurality of green sheets are obtained.

A metallization paste for forming the conductor layer 400 is obtained by, for example, adding electrically conductive powder of tungsten, molybdenum, or the like to a mixture containing alumina powder, an acrylic binder, and an organic solvent, followed by kneading. The obtained metallization paste is applied by using, for example, a screen printing apparatus, whereby the conductor layer 400 is formed on a particular green sheet.

Next, as shown in FIG. 4B, a hole 200 for forming the first gas flow passage 12 (the first vertical flow passage portion 120) is formed in the first laminate 400 at a predetermined location. The hole 200 is provided such that the hole 200 penetrates the first laminate 400 in the thickness direction and has an approximately cylindrical shape. The hole 200 is formed in the first laminate 400 at a predetermined location by using a known machining apparatus (a router or the like).

Next, as shown in FIG. 4C, a first porous body paste 7 for forming the first porous body 70 is injected into the hole 200 of the first laminate 400. The first porous body paste 7 is obtained by, for example, kneading a mixture containing alumina powder, a pore-forming material, a binder, an organic solvent, etc. The amounts of the alumina powder, the pore-forming material, etc. used for preparation of the first porous body paste 7 are appropriately set such that the purity of the first skeleton portion of the first porous body 70 and the porosity, etc. of the first porous body 70 become predetermined values.

Examples of the method of injecting the first porous body paste 7 into the hole 200 include a method using an injection molding apparatus and a method using a screen printing apparatus. Notably, the first laminate 110 with the first porous body paste 7 injected into the hole 200 is appropriately dried.

Notably, the outer periphery of the first laminate 110 may be cut if necessary. Subsequently, the first laminate is cut by means of machining so as to produce a disc-shaped compact. Subsequently, the obtained compact is fired for debinding, and the compact having undergone the firing for debinding is fired (main firing), whereby the fired body is obtained.

Since the first laminate 110 for forming the plate-shaped member 11 and the first porous body paste 7 injected into the hole 200 for forming the first porous body 70 are simultaneously fired as described above, the first porous body 70 and the first vertical flow passage portion 120 (the plate-shaped member 11) are united with each other by means of solid phase bonding. Notably, the size of the hole 200 and the amount, etc. of the first porous body paste 7 injected into the hole 200 are appropriately set in consideration of shrinkage at the time of firing.

Subsequently, the surface of the fired body is subjected to polishing or the like, whereby the holding substrate 10 including the plate-shaped member 11 as shown in FIG. 4D is obtained.

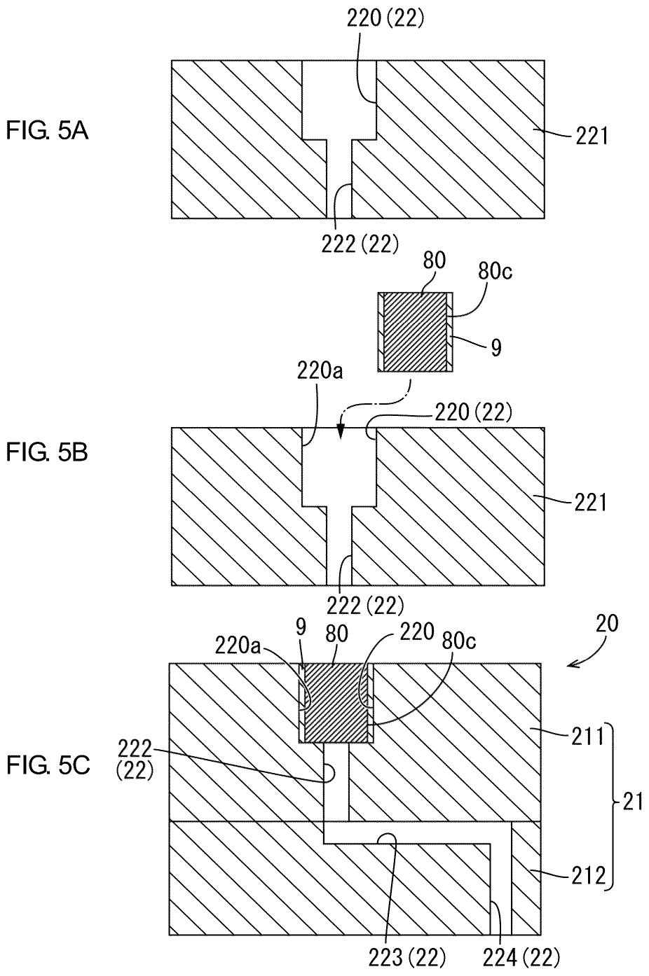

Next, a method of producing the base 20 will be described with reference to FIGS. 5A-5C. FIGS. 5A-5C are a set of explanatory views schematically representing the method of producing the base 20. First, as shown in FIG. 5A, a first plate-shaped base member 211 formed of a metallic material such as aluminum is prepared, and the second vertical flow passage portion 220 and the vertical flow passage portion 222 of the second gas flow passage 22 are formed by, for example, cutting the first plate-shaped base member 211 at predetermined locations. The second vertical flow passage portion 220 and the vertical flow passage portion 222 are formed by a known pore-forming method. This first plate-shaped base member 211 constitutes a portion of the plate-shaped base member 21 on the upper side (the third surface S3 side).

Subsequently, as shown in FIG. 5B, the separately produced, sintered second porous body 80 with uncured adhesive 9 applied to its circumferential surface 80c is disposed in the second vertical flow passage portion 220 of the first plate-shaped base member 211.

The second porous body 80 is formed by sintering a second porous body paste for forming the second porous body 80. The second porous body paste is obtained by, for example, kneading a mixture containing alumina powder, a pore-forming material, a binder (glass component), an organic solvent, etc. The amounts of the alumina powder, the pore-forming material, etc. used for preparation of the second porous body paste are appropriately set such that the purity of the second skeleton portion of the second porous body 80 and the porosity, etc. of the second porous body 80 become predetermined values. A circular columnar compact is produced from the second porous body paste, and firing for debinding and main firing are performed for the compact, whereby the second porous body 80 is obtained. Notably, since a larger amount of a binder (glass component) for facilitating bonding between particles of ceramic powder (alumina powder) by sintering can be used for the second porous body 80 as compared with the first porous body 70, the degree of freedom in determining the size of pores, etc. increases, and gas permeability is easily secured.

No particular limitation is imposed on the adhesive 9 so long as the adhesive 9 has heat resistance and can bond together the second porous body 80 (for example, ceramic material) and the first plate-shaped base member 211 (for example, metallic material). For example, silicone resin is used. The uncured adhesive 9 may be applied to the entirety of the circumferential surface 80c of the second porous body 80 or a portion of the circumferential surface 80c.

After the second porous body 80 with the adhesive 9 having been disposed in the second vertical flow passage portion 220 of the first plate-shaped base member 211, the adhesive 9 is cured, for example, by heating the first plate-shaped base member 211, if necessary.

Subsequently, as shown in FIG. 5C, a second plate-shaped base member 212 formed of the same metallic material as the first plate-shaped base member 211 is prepared, and the horizontal flow passage portion 223 and the vertical flow passage portion 224 of the second gas flow passage 22 are formed by, for example, cutting the second plate-shaped base member 212 at predetermined locations. Subsequently, the upper surface of the second plate-shaped base member 212 in which the horizontal flow passage portion 223 and the vertical flow passage portion 224 have been formed and the lower surface of the first plate-shaped base member 211 in which the second porous body 80 has been disposed in the second gas flow passage 22 (the second vertical flow passage portion 220) are joined together by a known joining technique such as brazing, EB welding, etc., whereby the base 20 including the plate-shaped base member 20 is obtained.

After the holding substrate 10 and the base 20 have been produced, they are joined together by using the joining material 30. The joining of the holding substrate 10 and the base 20 by the joining material 30 is basically the same as the joining in conventional products. Therefore, the joining will not be described in detail. The holding device 100 is produced in the above-described manner.

### Embodiment 2

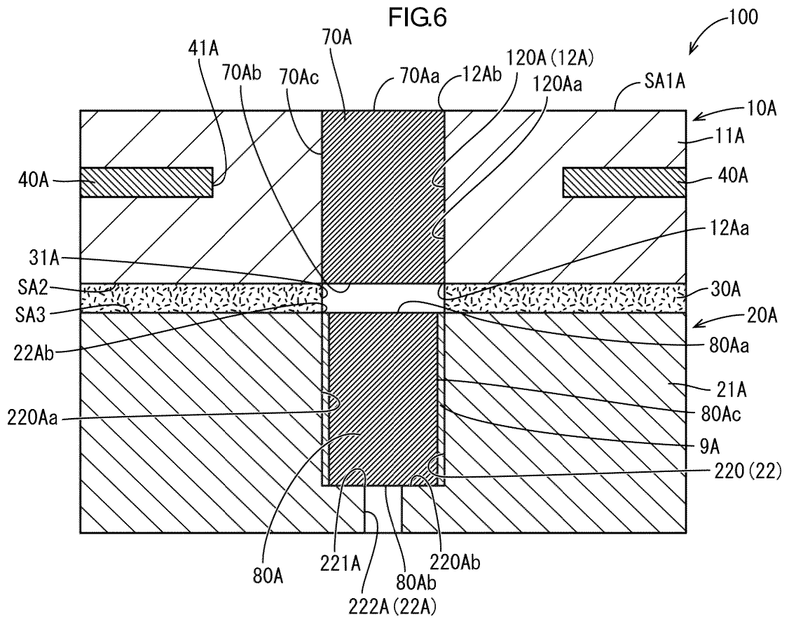

Next, a holding device 100A according to Embodiment 2 will be described with reference to FIG. 6. FIG. 6 is a sectional view of the holding device 100A according to Embodiment 2, which shows, on an enlarged scale, an area where a first gas flow passage 12A and a second gas flow passage 22A are connected and its vicinity. The basic structures of a holding substrate 10A and a base 20A of the present embodiment are the same as those of Embodiment 1. Therefore, in FIG. 6, portions corresponding to the portions of Embodiment 1 are denoted by the same symbols as those of Embodiment 1 with symbol “A” added thereto, and their detailed description is omitted.

The holding substrate 10A includes a disc-like, plate-shaped member 11A and the first gas flow passage 12A formed therein. A surface of the plate-shaped member 11A on the upper side serves as a first surface SA1 of the holding substrate 10A, and a surface of the plate-shaped member 11A on the lower side serves as a second surface SA2 of the holding substrate 10A. The base 20A includes a disc-like, plate-shaped base member 21A and the second gas flow passage 22A formed in the plate-shaped base member 21A. A surface of the plate-shaped base member 21A on the upper side serves as a third surface SA3 of the base 20A, and a surface of the plate-shaped base member 21A on the lower side serves as a fourth surface (not shown) of the base 20A.

In the holding device 100A of the present embodiment, as in Embodiment 1, a first porous body 70A is disposed in a first vertical flow passage portion 120A of the first gas flow passage 12A, and a second porous body 80A is disposed in a second vertical flow passage portion 220A of the second gas flow passage 22A. In addition, in the case of the present embodiment as well, as in Embodiment 1, the resistance to plasma (plasma resistance) of the first porous body 70A is set to be higher than the resistance to plasma (plasma resistance) of the second porous body 80A.

However, in the case of the present embodiment, the ceramic material which constitutes the first porous body 70A is yttria, and the ceramic material which constitutes the second porous body 80A is alumina. As in this case, yttria which is more excellent in resistance to plasma than alumina may be used as the ceramic material which constitutes the first porous body 70A which is more likely to be exposed to plasma.

No particular limitation is imposed on the purity of the ceramic material (yttria) which constitutes the first porous body 70A so long as the purpose of the present invention is not impaired. However, the purity of the ceramic material which constitutes the first porous body 70A is, for example, preferably 99.0% or higher, more preferably 99.9% or higher.

In addition, no particular limitation is imposed on the purity of the ceramic material (alumina) which constitutes the second porous body 80A so long as the purpose of the present invention is not impaired. However, the purity of the ceramic material which constitutes the second porous body 80A is, for example, preferably 95.0% or higher, more preferably 97.0% or higher.

Notably, in the case of the present embodiment as well, as in Embodiment 1, it is preferred that the purity of the ceramic material (yttria) of the first porous body 70A is higher than the purity of the ceramic material (alumina) of the second porous body 80A.

The purities of the ceramic materials of the first porous body 70A and the second porous body 80A can be adjusted by appropriately setting the purities of ceramic powders (yttria powder and alumina powder) used in production of the first porous body 70A and the second porous body 80A and the amounts of components to be used other than ceramic powders (for example, binder, dispersant, plasticizer, etc.).

In addition, in the case of the present embodiment as well, as in Embodiment 1, the porosity of the second porous body 80A is preferably set to be equal to or higher than the porosity of the first porous body 70A. Setting the porosity of the first porous body 70A and the porosity of the second porous body 80A in the above-described manner makes it easy to set the resistance to plasma of the second porous body 80A to be higher than the resistance to plasma of the first porous body 70A.

Notably, no particular limitation is imposed on the porosity of the first porous body 70A so long as the purpose of the present invention is not impaired. However, the porosity of the first porous body 70A is, for example, preferably 50% or higher, more preferably 55% or higher, further preferably 60% or higher, and preferably 80% or lower, more preferably 75% or lower, further preferably 70% or lower. When the porosity of the first porous body 70A falls in such ranges, it is easy to set the porosity of the second porous body 80A to be equal to or higher than the porosity of the first porous body 70 while securing the gas permeabilities of the first porous body 70A and the second porous body 80A.

In the holding device 100A of the present embodiment, as described above, the ceramic material which constitutes the first porous body 70A is yttria, and the ceramic material which constitutes the second porous body 80A is alumina, whereby the resistance to plasma (plasma resistance) of the first porous body 70A is set to be higher than the resistance to plasma (plasma resistance) of the second porous body 80A. Therefore, in particular, damage of the first porous body 70A by plasma is suppressed, while the gas permeability of the first porous body 70A is secured.

As in Embodiment 1, the holding device 100A of the present embodiment includes the first porous body 70A and the second porous body 80A (examples of the porous body) which are provided in the first gas flow passage 12A and the second gas flow passage 22A (examples of the gas flow passage) for supplying the inert gas and which are excellent in plasma resistance while having gas permeability.

### Embodiment 3

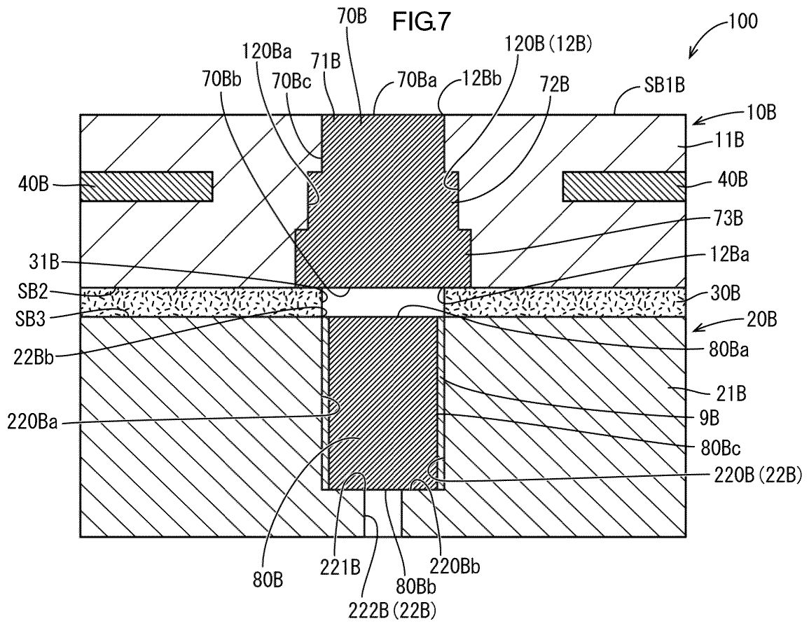

Next, a holding device 100B according to Embodiment 3 will be described with reference to FIG. 7. FIG. 7 is a sectional view of the holding device 100B according to Embodiment 3, which shows, on an enlarged scale, an area where a first gas flow passage 12B and a second gas flow passage 22B are connected and its vicinity. The basic structures of a holding substrate 10B and a base 20B of the present embodiment are the same as those of Embodiment 1. Therefore, in FIG. 7, portions corresponding to the portions of Embodiment 1 are denoted by the same symbols as those of Embodiment 1 with symbol “B” added thereto, and their detailed description is omitted.

The holding substrate 10B includes a disc-like, plate-shaped member 11B and the first gas flow passage 12B formed therein. A surface of the plate-shaped member 11B on the upper side serves as a first surface SB1 of the holding substrate 10B, and a surface of the plate-shaped member 11B on the lower side serves as a second surface SB2 of the holding substrate 10B. The base 20B includes a disc-like, plate-shaped base member 21B and the second gas flow passage 22B formed in the plate-shaped base member 21B. A surface of the plate-shaped base member 21B on the upper side serves as a third surface SB3 of the base 20B, and a surface of the plate-shaped base member 21B on the lower side serves as a fourth surface (not shown) of the base 20B.

In the holding device 100B of the present embodiment, as in Embodiment 1, a first porous body 70B is disposed in a first vertical flow passage portion 120B of the first gas flow passage 12B, and a second porous body 80B is disposed in a second vertical flow passage portion 220B of the second gas flow passage 22B. In addition, in the case of the present embodiment, as in Embodiment 1, the ceramic material which constitutes the first porous body 70B is alumina, and the ceramic material which constitutes the second porous body 80B is alumina. In addition, in the case of the present embodiment as well, as in Embodiment 1, the resistance to plasma (plasma resistance) of the first porous body 70B is set to be higher than the resistance to plasma (plasma resistance) of the second porous body 80B.

However, in the case of the present embodiment, the shape of the first gas flow passage 12B (the first vertical flow passage portion 120B) formed in the plate-shaped member 11B of the holding substrate 10B and the shape of the first porous body 70B disposed in the first gas flow passage 12B (the first vertical flow passage portion 120B) differ from those of Embodiment 1. The first porous body 70B of the present embodiment has a stepped shape such that the outer diameter increases stepwise from the first surface SB1 side toward the second surface SB2 side. The first porous body 70B is composed of a disc-shaped small diameter portion 71B, a disc-shaped intermediate diameter portion 72B having an outer diameter greater than that of the small diameter portion 71B, and a disc-shaped large diameter portion 73B having an outer diameter greater than that of the intermediate diameter portion 72B. The small diameter portion 71B, the intermediate diameter portion 72B, and the large diameter portion 73B are concentrically stacked in this order from the first surface SB1 side toward the second surface SB2. The first vertical flow passage portion 120B of the first gas flow passage 12B, in which the first porous body 70B is disposed, has a stepped shape such that the inner diameter increases stepwise from the first surface SB1 side toward the second surface SB2 side. Notably, an upper end surface of the small diameter portion 71B serves as an upper end surface 70Ba of the first porous body 70B, and a lower end surface of the large diameter portion 73B serves as a lower end surface 70Bb of the first porous body 70B.

As in Embodiment 1, a first gas outlet 12Bb of the first gas flow passage 12B has a circular shape in the plan view. A first gas inlet 12Ba of the first gas flow passage 12B has a circular shape larger than that of the first gas outlet 12Bb in the plan view. The first gas outlet 12Bb has a circular shape larger than that of a second gas outlet 22Bb of the second gas flow passage 22B in the plan view and is opposed to the second gas outlet 22Bb.

A circumferential surface (an outer surface other than the upper end surface 70Ba and the lower end surface 70Bb) 70Bc of the first porous body 70B and an inner circumferential surface 120Ba of the first vertical flow passage portion 120B (the plate-shaped member 11B) are joined to each other by means of sintering. The first porous body 70B and the first vertical flow passage portion 120B (the plate-shaped member 11B) are united with each other by means of solid phase bonding.

Notably, the purities, porosities, etc. of the ceramic materials which constitute the first porous body 70B and the second porous body of the present embodiment are appropriately adjusted in the same manner as in Embodiment 1 such that the resistance to plasma (plasma resistance) of the first porous body 70B becomes higher than the resistance to plasma (plasma resistance) of the second porous body 80B.

In the holding device 100B of the present embodiment, in the plan view, the lower end surface 70Bb of the stepped first porous body 70B is more likely to overlap with the upper end surface 80Ba of the circular columnar second porous body 80B disposed in the second vertical flow passage portion 220B. As in this case, the shape of the first porous body 70B and the shape of the second porous body 80B may differ from each other, and the lower end surface 70Bb of the first porous body 70B may be larger than the upper end surface 70Ba of the second porous body 80B.

In the holding device 100B of the present embodiment, as described above, the resistance to plasma (plasma resistance) of the first porous body 70B is set to be higher than the resistance to plasma (plasma resistance) of the second porous body 80B. Therefore, in particular, damage of the first porous body 70B by plasma is suppressed, while the gas permeability of the first porous body 70B is secured.

As in Embodiment 1, the holding device 100B of the present embodiment includes the first porous body 70B and the second porous body 80B (examples of the porous body) which are provided in the first gas flow passage 12B and the second gas flow passage 22B (examples of the gas flow passage) for supplying the inert gas and which are excellent in plasma resistance while having gas permeability.

### Embodiment 4

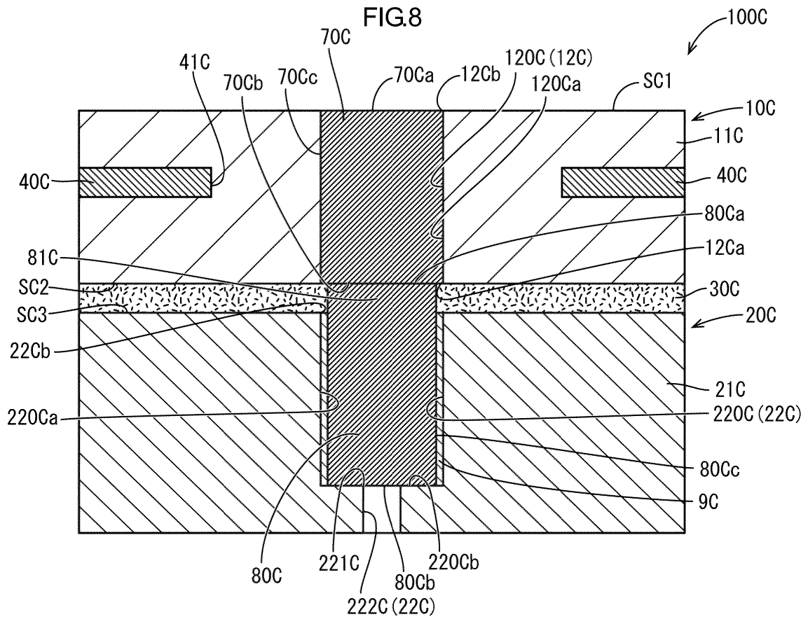

Next, a holding device 100C according to Embodiment 4 will be described with reference to FIG. 8. FIG. 8 is a sectional view of the holding device 100C according to Embodiment 4, which shows, on an enlarged scale, an area where a first gas flow passage 12C and a second gas flow passage 22C are connected and its vicinity. The basic structures of a holding substrate 10C and a base 20C of the present embodiment are the same as those of Embodiment 1. Therefore, in FIG. 8, portions corresponding to the portions of Embodiment 1 are denoted by the same symbols as those of Embodiment 1 with symbol “C” added thereto, and their detailed description is omitted.

In the holding device 100C of the present embodiment, as in Embodiment 1, a first porous body 70C is disposed in a first vertical flow passage portion 120C of the first gas flow passage 12C, and a second porous body 80C is disposed in a second vertical flow passage portion 220C of the second gas flow passage 22C. In addition, in the case of the present embodiment, as in Embodiment 1, the ceramic material which constitutes the first porous body 70C is alumina, and the ceramic material which constitutes the second porous body 80C is alumina. In addition, in the case of the present embodiment as well, as in Embodiment 1, the resistance to plasma (plasma resistance) of the first porous body 70C is set to be higher than the resistance to plasma (plasma resistance) of the second porous body 80C.

However, in the case of the present embodiment, an upper end 81C of the second porous body 80C is configured to protrude upward (toward the holding substrate 10C side) from the second gas outlet 22Cb of the second vertical flow passage portion 220C such that an upper end surface 80Ca of the second porous body 80C butts against a lower end surface 70Cb of the first porous body 70C. Namely, the length of the second porous body 80C of the present embodiment in the upward/downward direction is set to be long such that the second porous body 80C fills the gap formed, for example, between the first porous body 70 and the second porous body 80 of Embodiment 1. An adhesive 9C is interposed between a circumferential surface 80Cc of the second porous body 80C and a circumferential surface 220Ca of the second vertical flow passage portion 220C, and the second porous body 80C is fixed in the second vertical flow passage portion 220C by using the adhesion force of the adhesive 9C.

Notably, a joining material 30C is disposed around the upper end 81C of the second porous body 80C which protrudes from the second gas outlet 22Cb disposed on the third surface SC3 side. The holding substrate 10C and the base 20C are joined to each other by the joining material 30C intervening therebetween.

A circumferential surface 70Cc of the first porous body 70C and an inner circumferential surface 120Ca of the first vertical flow passage portion 120C (the plate-shaped member 11C) are joined to each other by means of sintering. Namely, the first porous body 70C and the first vertical flow passage portion 120C (the plate-shaped member 11C) are united with each other by means of solid phase bonding.

Notably, the purities, porosities, etc. of the ceramic materials which constitute the first porous body 70C and the second porous body 80C of the present embodiment are appropriately adjusted in the same manner as in Embodiment 1 such that the resistance to plasma (plasma resistance) of the first porous body 70C becomes higher than the resistance to plasma (plasma resistance) of the second porous body 80C.

In the holding device 100C of the present embodiment, as described above, the upper end 81C of the second porous body 80C may be configured to protrude upward from the second gas outlet 22Cb located on the third surface SC3 such that the upper end surface 80Ca of the second porous body 80C butts against the lower end surface 70Cb of the first porous body 70C.

### Embodiment 5

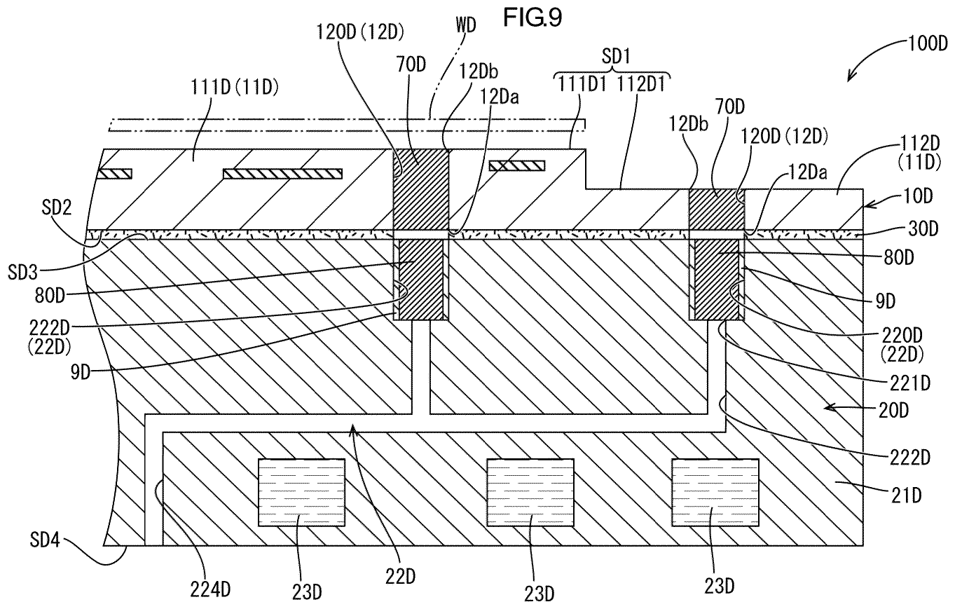

Next, a holding device 100D according to Embodiment 5 will be described with reference to FIG. 9. FIG. 9 is an explanatory view schematically representing the sectional structure of a portion of the holding device 100D according to Embodiment 5. In FIG. 9, portions corresponding to the portions of Embodiment 1 are denoted by the same symbols as those of Embodiment 1 with symbol “D” added thereto, and their detailed description is omitted.

A holding substrate 10D includes a disc-like, plate-shaped member 11D and a first gas flow passage 12D formed therein.

The plate-shaped member 11D has a disc-shaped placing portion 111D which is located on the center side in the plan view and has a predetermined thickness, and an annular flange portion 112D extending radially outward from the placing portion 111D. The flange portion 112D has a thickness smaller than that of the placing portion 111D, and an upper surface 112D1 of the flange portion 112D is lower in height than an upper surface 111D1 of the placing portion 111D. A wafer WD is placed on the upper surface 111D1 of the placing portion 111D. The upper surface 111D1 of the placing portion 111D has a circular shape in the plan view, and the upper surface 112D1 of the flange portion 112D has an annular shape which surrounds the placing portion 111D in the plan view. An unillustrated annular ring (focus ring) is disposed on the upper surface 112D1 of the flange portion 112D.

Notably, a first surface SD1 of the holding substrate 10D is composed of the upper surface 111D1 of the placing portion 111D and the upper surface 112D1 of the flange portion 112D. A second surface SD2 of the holding substrate 10D is composed of a lower surface of the plate-shaped member 11D.

The base 20D includes a disc-like, plate-shaped base member 21D and a second gas flow passage 22D formed in the plate-shaped base member 21D. A refrigerant flow passage 23D is provided in the base 20D. Notably, an upper surface of the plate-shaped base member 21D serves as a third surface SD3 of the base 20D, and a lower surface of the plate-shaped base member 21D serves as a fourth surface SD4 of the base 20D.

The holding substrate 10D and the base 20CD are joined to each other by a joining material 30D interposed therebetween.

In the case of the present embodiment, the first gas outlet 12 Db is formed not only on the upper surface 111D1 of the placing portion 111D but also on the upper surface 112D1 of the flange portion 112D. As in Embodiment 1, etc., a plurality of (many) first gas outlets 12 Db are provided on the upper surface 111D1 of the placing portion 111D. A plurality of first gas outlets 12 Db are provided on the upper surface 112D1 of the flange portion 112D as well. In the case of the present embodiment, the first vertical flow passage portion 120D of the first gas flow passage 12D is provided not only in the placing portion 111D but also in the flange portion 112D, and first porous bodies 70D are disposed in their first vertical flow passage portions 120D.

The first gas flow passage 12D formed in the flange portion 112D is composed of a hole which penetrates the holding substrate 10D in the thickness direction (the upward/downward direction) and which includes a first gas inlet 12Da which is open toward the second surface SD2 side of the holding substrate 10D (the plate-shaped substrate 11D) and a gas outlet 12 Db which is open toward the upper surface 112D1 side (the first surface SD1 side) of the flange portion 112D.

The first gas flow passage 12D formed in the placing portion 111D is composed of a hole which penetrates the holding substrate 10D in the thickness direction (the upward/downward direction) and which includes a first gas inlet 12Da which is open toward the second surface SD2 side of the holding substrate 10D (the plate-shaped substrate 11D) and a gas outlet 12 Db which is open toward the upper surface 111D1 side (the first surface SD1 side) of the placing portion 111D.

Notably, a second porous body 80D is disposed in the second vertical flow passage portion 220D of the second gas flow passage 22D formed in the base 20D.

In the case of the present embodiment as well, as in Embodiment 1, the ceramic material which constitutes the first porous body 70D is alumina, and the ceramic material which constitutes the second porous body 80D is alumina. In addition, in the case of the present embodiment as well, as in Embodiment 1, the resistance to plasma (plasma resistance) of the first porous body 70D is set to be higher than the resistance to plasma (plasma resistance) of the second porous body 80D.

As in the present embodiment, the resistance to plasma (plasma resistance) of the first porous body 70D may be set to be higher than the resistance to plasma (plasma resistance) of the second porous body 80D not only in the gas flow passage 22D of the placing portion 111D, on which the wafer WD is placed, but also in the gas flow passage 22D of the flange portion 112D.

### Other embodiments

The present invention is not limited to the embodiments described by the above description and the drawings, and, for example, the following embodiments are contained in the technical scope of the present invention.
(1) The upper end surface of the first porous body exposed from the first gas outlet may have a shape other than the circular shape (polygonal shape, etc.) so long as the purpose of the present invention is not impaired.
(2) The upper end surface of the porous body may be disposed below the first surface so long as the purpose of the present invention is not impaired. Namely, the first gas flow passage may have a tubular vertical flow passage portion (unfilled vertical flow passage portion) in which the first porous body is not disposed, on the upper side of the first vertical flow passage portion in which the first porous body is disposed.
(3) Another embodiment may be such that, for example, the ceramic material of the first porous body of the above-described Embodiment 3 is formed of yttria and the ceramic material of the second porous body is formed of alumina.
(4) The holding device producing method shown in the above-described embodiments is one example, and the holding device may be produced by other methods so long as the purpose of the present invention is not impaired.
(5) Although the base may be a metal base whose plate-shaped base member is formed of a metallic material as in Embodiment 1, etc., the present invention is not limited thereto, and in other embodiments, the base may be, for example, a ceramic base whose plate-shaped base member is formed of a ceramic material, a composite base whose plate-shaped base member is formed of a composite material of a metallic material and a ceramic material, or a ceramic base with a metal layer provided on the third surface side of the ceramic base.
(6) In Embodiment 1, etc., a dense layer which is denser than the first porous body or the second porous body may be provided on the side surface of the first porous body or the second porous body.
(7) In the fourth embodiment, the upper end 81C of the second porous body 80C is configured to protrude upward (toward the holding substrate 10C side) from the second gas outlet 22Cb of the second vertical flow passage portion 220C. In the fourth embodiment, the length of the second porous body 80C in the upward/downward direction is set to be long such that the second porous body 80C fills the gap formed between the first porous body 70C and the second porous body 80C. However, a gap of a certain size which does not affect discharge may be provided between the first porous body 70C and the second porous body 80C.

### DESCRIPTION OF REFERENCE NUMERALS AND SYMBOLS

100: holding device, 10: holding substrate, 11: plate-shaped member, 12: first gas flow passage, 120: first vertical flow passage portion, 12a: first gas inlet, 12b: first gas outlet, 20: base, 21: plate-shaped base member, 22: second gas flow passage, 22a: second gas inlet, 22b: second gas outlet, 220: second vertical flow passage portion, 70: first porous body, 80: second porous body, S1: first surface, S2: second surface, W: wafer (object)

1. A holding device comprising:
a holding substrate which includes a plate-shaped member having a first surface and a second surface located on a side opposite the first surface, a first gas flow passage formed in the plate-shaped member and having a first gas outlet which is open to the first surface side and a first gas inlet which is open to the second surface side, and a gas permeable first porous body disposed in the first gas flow passage and containing a ceramic material as a main component; and
a base which includes a plate-shaped base member disposed on the second surface side of the plate-shaped member and having a third surface opposed to the second surface and a fourth surface located on a side opposite the third surface, a second gas flow passage formed in the plate-shaped base member and having a second gas outlet which is open to the third surface side and is opposed to the first gas inlet, and a gas permeable second porous body disposed in the second gas flow passage and containing a ceramic material as a main component, wherein
the first gas flow passage has a first vertical flow passage portion which extends from the first gas inlet toward the first surface side and in which the first porous body is disposed,
the second gas flow passage has a second vertical flow passage portion which extends from the second gas outlet toward the fourth surface side and in which the second porous body is disposed in such a manner as to overlap with the first porous body in a plan view, and
the first porous body is higher in plasma resistance than the second porous body.

2. A holding device according to claim 1, wherein the ceramic material of the first porous body is higher in purity than the ceramic material of the second porous body.

3. A holding device according to claim 1, wherein the ceramic material of the first porous body is alumina, and the ceramic material of the second porous body is alumina.

4. A holding device according to claim 1, wherein the ceramic material of the first porous body is yttria, and the ceramic material of the second porous body is alumina.

5. A holding device according to claim 1, wherein the first porous body has a porosity of 50 to 80% and the second porous body has a porosity equal to or higher than the porosity of the first porous body.

6. A holding device according to claim 1, wherein the first vertical flow passage portion extends in a thickness direction of the plate-shaped member so as to connect the first gas outlet and the first gas inlet, and the first porous body is disposed to fill the first vertical flow passage portion from the first gas outlet side to the first gas inlet.

7. A holding device according to claim 1, wherein the plate-shaped member contains a ceramic material as a main component, and the plate-shaped member and the first porous body are joined to each other by means of sintering.

8. A holding device according to claim 1, wherein each of the first porous body and the second porous body contains a glass component, and the first porous body is smaller in glass content than the second porous body.
